(19) United States
(12) Patent Application Publication
(10) Pub. No.: US 2014/0118953 A1
(43) Pub. Date: May 1, 2014

(54) HEAT DISSIPATION STRUCTURE

(71) Applicant: HON HAI PRECISION INDUSTRY CO., LTD., New Taipei (TW)

(72) Inventors: WEI-LUNG HUANG, New Taipei (TW); CHUN-YUAN TIEN, New Taipei (TW); CHIH-HUNG WU, New Taipei (TW)

(73) Assignee: HON HAI PRECISION INDUSTRY CO., LTD., New Taipei (TW)

(21) Appl. No.: 14/066,738

(22) Filed: Oct. 30, 2013

(30) Foreign Application Priority Data
Oct. 29, 2012 (TW) 101140006

(51) Int. Cl. H05K 1/02

(52) U.S. Cl. CPC H05K 1/021
USPC 361/720

(57) ABSTRACT

An exemplary heat dissipation structure includes a circuit board, at least one electronic element, and a heat sink. The electronic element is mounted on the circuit board to form a circuit. The heat sink is mounted on the circuit board corresponding to the electronic element to dissipate heat generated by the electronic element. The heat sink is mounted by surface mount technology.

### BACKGROUND

1. Technical Field

The present disclosure relates to heat dissipation structures, and particularly, to a heat dissipation structure of a circuit board.

2. Description of Related Art

A motherboard of a computer includes a number of direct current converters having different phases for providing power signals to a number of different elements on the motherboard. Generally, only one heat sink is mounted on the direct current converters to dissipate heat. A heat dissipating capacity of the heat sink is designed according to a heat summation of the direct current converters. However, differences of heat generated by the direct current converters having different phases are huge. Therefore, a heat dissipating efficiency of the one heat sink for all the direct current converters is low. The heat sink is bulky and is required to be fixed to the motherboard via a number of threaded bolts passing through a number of through holes defined in the motherboard, which adversely affects a wiring space of the motherboard and increases manufacturing cost of the motherboard.

Therefore, it is desirable to provide a means which can overcome the above-mentioned shortcomings

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the views, and all the views are schematic.

FIG. 1 is a disassembled schematic view of a heat dissipation structure in accordance with an exemplary embodiment.

FIG. 2 is an assembled schematic view of the heat dissipation structure of FIG. 1.

FIG. 3 is a schematic side view of the heat dissipation structure of FIG. 2.

### DETAILED DESCRIPTION

The disclosure is illustrated by way of example and not by way of limitation in the figures of the accompanying drawings, in which like reference numerals indicate similar elements. It should be noted that references to “an” or “one” embodiment in this disclosure are not necessarily to the same embodiment, and such references can mean “at least one.”

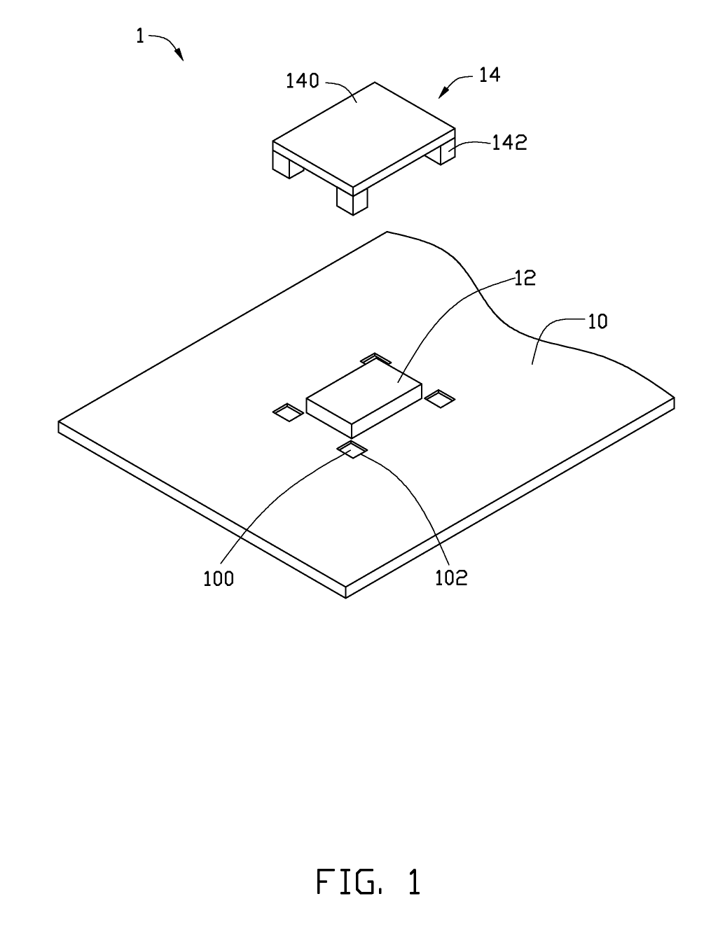

Referring to FIG. 1, a heat dissipation structure 1 includes a circuit board 10, at least one electronic element 12, and a heat sink 14. The heat sink 14 is positioned on the circuit board 10 to dissipate heat of the electronic element 12. The heat sink 14 is positioned on the circuit board 10 using a surface mount technology (SMT). That is, the circuit board 10 and the heat sink 14 mounted on the circuit board 10 cooperatively form a surface-mount assembly.

The electronic element 12 is mounted on the circuit board 10 and connected with the other electronic elements (not shown) via internal wirings of the circuit board 10 to form a circuit having a specific function. The circuit board 10 includes a grounding layer 100. The electronic element 12 on the circuit board 10 is grounded via the grounding layer 100. In this embodiment, the circuit board 10 is a motherboard of a computer. The grounding layer 100 is a copper foil. The electronic element 12 is a direct current converter.

The heat sink 14 includes a heat dissipating sheet 140 and a number of connecting feet 142 extending from the heat dissipating sheet 140. The connecting feet may be integrated formed with the heat dissipating sheet 140 or separately connected to the heat dissipating sheet 140 via heat conductive glue. Both of the connecting feet 142 and the heat dissipating sheet 140 are made of a material with high thermal conductivity. In this embodiment, the connecting feet 142 are integrated formed with the heat dissipating sheet 140. The heat dissipating sheet 140 is a rectangular sheet. The connecting feet 142 correspondingly extend from four corners of the heat dissipating sheet 140.

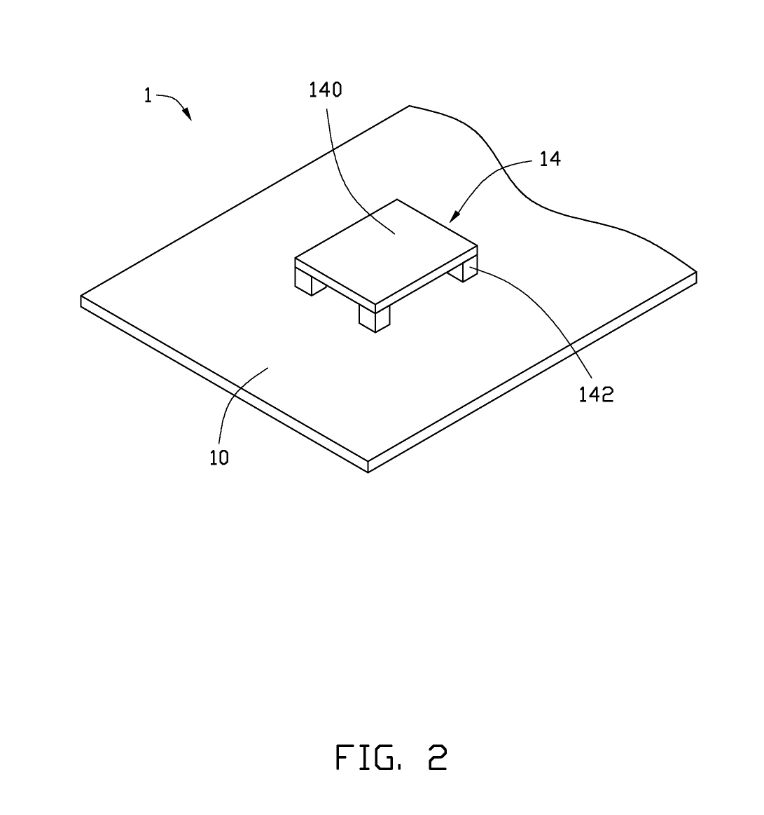

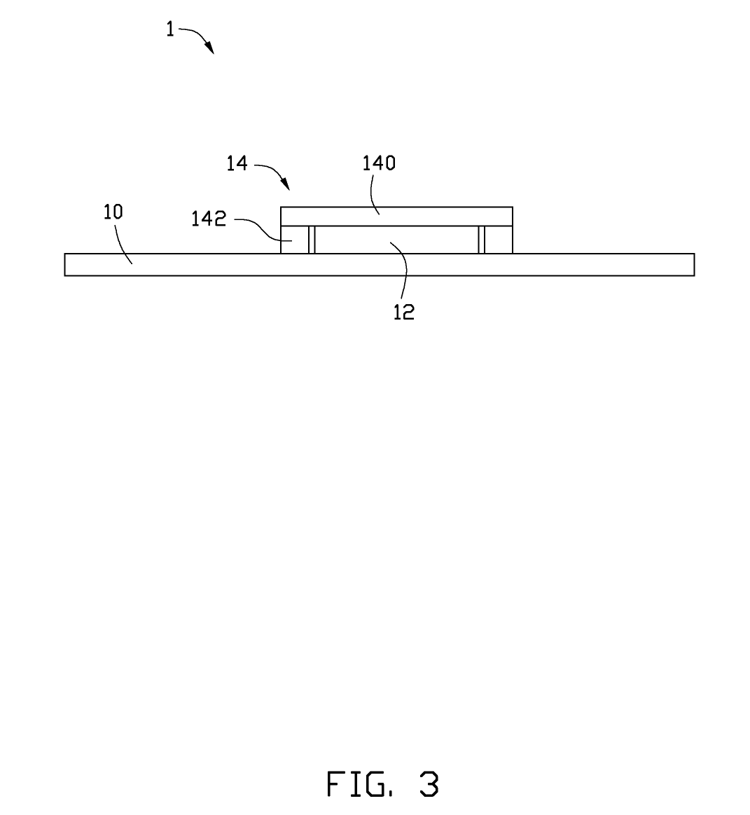

Referring also to FIGS. 2 and 3, the circuit board 10 defines a number of connecting holes 102 encircling the electronic element 12. The number of the connecting holes 102 is corresponding to the number of the connecting feet 142. The grounding layer 100 is exposed in the connecting holes 102. The connecting feet 142 are mounted in the connecting holes 102 via the SMT process. When the connecting feet 142 are mounted on the circuit board 10, the heat dissipating sheet 140 contacts with the electronic element 12 to dissipate the heat generated by the electronic element 12. Some heat from the electronic element 12 is dissipated from a top surface of the heat dissipating sheet 140. Other heat from the electronic element 12 is transmitted to the grounding layer 100 via the heat dissipating sheet 140 and the connecting feet 142 and further dissipated in the grounding layer 100.

The heat sink 14 can be standardized and mass produced. The size of the heat sink 14 can be flexibly adjusted according to heat of electronic element 12. Therefore, the heat dissipating efficiency of the heat dissipation structure 1 is improved and the cost of the heat sink 14 is decreased. Furthermore, the heat sink 14s are mounted onto the circuit board 10 via an SMT machine, the manufacturing efficiency of heat dissipation is also improved.

While various embodiments have been described, it is to be understood that the present disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A heat dissipation structure, comprising:
a circuit board;
at least one electronic element positioned the circuit board; and
a heat sink positioned on the circuit board and in contact with the electronic element, wherein the heat sink is positioned using a surface mount technology, the circuit board and the heat sink mounted on the circuit board cooperatively form a surface-mount assembly.

2. The heat dissipation structure of claim 1, wherein the heat sink comprises a heat dissipating sheet and a plurality of connecting feet extending from the heat dissipating sheet.

3. The heat dissipation structure of claim 2, wherein the circuit board comprises a grounding layer, the circuit board defines a plurality of connecting holes encircling the element, the grounding layer is exposed in the connecting holes, and the connecting feet are mounted in the connecting holes.

4. The heat dissipation structure of claim 2, wherein the electronic element contacts the heat dissipating sheet.

5. The heat dissipation structure of claim 2, wherein the connecting feet extend from a periphery of a heat dissipating sheet.

6. The heat dissipation structure of claim 5, wherein the heat dissipating sheet is a rectangular sheet and the connecting feet correspondingly extend from four corners of the heat dissipating sheet.

7. The heat dissipation structure of claim 2, wherein the connecting feet are integrated formed with the heat dissipating sheet.

8. The heat dissipation structure of claim 7, wherein the connecting feet and the heat dissipating sheet are made of a material with high thermal conductivity.

9. The heat dissipation structure of claim 1, wherein one electronic element is corresponding to one heat sink.

10. The heat dissipation structure of claim 1, wherein the circuit board is a motherboard of a computer and the electronic element is a direct current converter.

11. The heat dissipation structure of claim 1, wherein the grounding layer is a copper foil.
